(19) United States
(12) Patent Application Publication
(10) Pub. No.: US 2019/0311766 A1
(43) Pub. Date: Oct. 10, 2019

(54) SEMICONDUCTOR DEVICE

(71) Applicant: TOSHIBA MEMORY CORPORATION, Minato-ku (JP)

(72) Inventor: Keiichi KUSHIDA, Kawasaki (JP)

(73) Assignee: TOSHIBA MEMORY CORPORATION, Minato-ku (JP)

(21) Appl. No.: 16/126,529

(22) Filed: Sep. 10, 2018

(30) Foreign Application Priority Data
Apr. 5, 2018 (JP) 2018-073259

(51) Int. Cl. G11C 11/419; H01L 27/11; G11C 5/14; G11C 7/18; G11C 8/14

(52) U.S. Cl. CPC G11C 11/419; H01L 27/1104; G11C 8/14; G11C 7/18; G11C 5/14

(57) ABSTRACT

A semiconductor device includes a latch including a first-node and a second-node. A first-transistor is between the first-node and a first-BL and has a gate connected to a WL. A second-transistor is between the second-node and a second-BL and has a gate connected to the WL. A power-supply line is connected to the latch. A third-transistor is connected between the first-node and a reference-voltage source. A fourth-transistor is between the second-node and the reference-voltage source and has a gate connected to the reference-voltage source. A signal line is connected to a gate of the third-transistor. In a first-mode, the power-supply line supplies a first-voltage to the latch and the signal line brings the third-transistor to a non-conduction state. In a second-mode, the power-supply line supplies a second-voltage to the latch and the signal line brings the third-transistor to a conduction state and connects the first-node to the reference-voltage source.

### CROSS REFERENCE TO RELATED APPLICATIONS

This application is based upon and claims the benefit of priority from the prior Japanese Patent Application No. 2018-073259, filed on Apr. 5, 2018, the entire contents of which are incorporated herein by reference.

### FIELD

The embodiments of the present invention relate to a semiconductor device.

### BACKGROUND

An SRAM (Static Random Access Memory) generally has characteristics of being volatile and incapable of retaining data when its power source is disconnected therefrom while having a high access rate. Further, an SRAM consumes a large amount of power when power supply is maintained in order to retain data. On the other hand, when a ROM (Read-Only memory) is added to an SRAM, there occurs a problem that its layout area is increased and the entire chip size is adversely increased.

### BRIEF DESCRIPTION OF THE DRAWINGS

FIG. 1 is a circuit diagram illustrating a configuration example of a semiconductor memory device 1 according to the present embodiment;

FIG. 2 is a circuit diagram illustrating an example of the internal configuration of the memory units;

FIG. 3 is a flowchart illustrating an example of a data read operation of the memory unit according to the present embodiment; and

FIG. 4 is a plan view illustrating an example of a schematic layout of the memory unit.

### DETAILED DESCRIPTION

Embodiments will now be explained with reference to the accompanying drawings. The present invention is not limited to the embodiments. The drawings are schematic or conceptual, and the ratios and the like among respective parts are not necessarily the same as those of actual products. In the present specification and the drawings, elements identical to those described in the foregoing drawings are denoted by like reference characters and detailed explanations thereof are omitted as appropriate. Hereinafter, “connecting” includes electric connection as well as direct connection.

A semiconductor device according to an embodiment comprises a latch circuit including a first node and a second node being capable of retaining data of polarities opposite to each other, respectively. A first transistor is electrically connected between the first node and a first bit line and has a gate electrode electrically connected to a word line. A second transistor is electrically connected between the second node and a second bit line and has a gate electrode electrically connected to the word line. A power-supply line is electrically connected to the latch circuit. A third transistor is electrically connected between the first node and a reference voltage source. A fourth transistor is electrically connected between the second node and the reference voltage source and has a gate electrode electrically connected to the reference voltage source. A signal line is electrically connected to a gate electrode of the third transistor. In a first mode, the power-supply line supplies a first voltage to the latch circuit and the signal line brings the third transistor to a non-conduction state. In a second mode, the power-supply line supplies a second voltage to the latch circuit and the signal line brings the third transistor to a conduction state and electrically connects the first node to the reference voltage source.

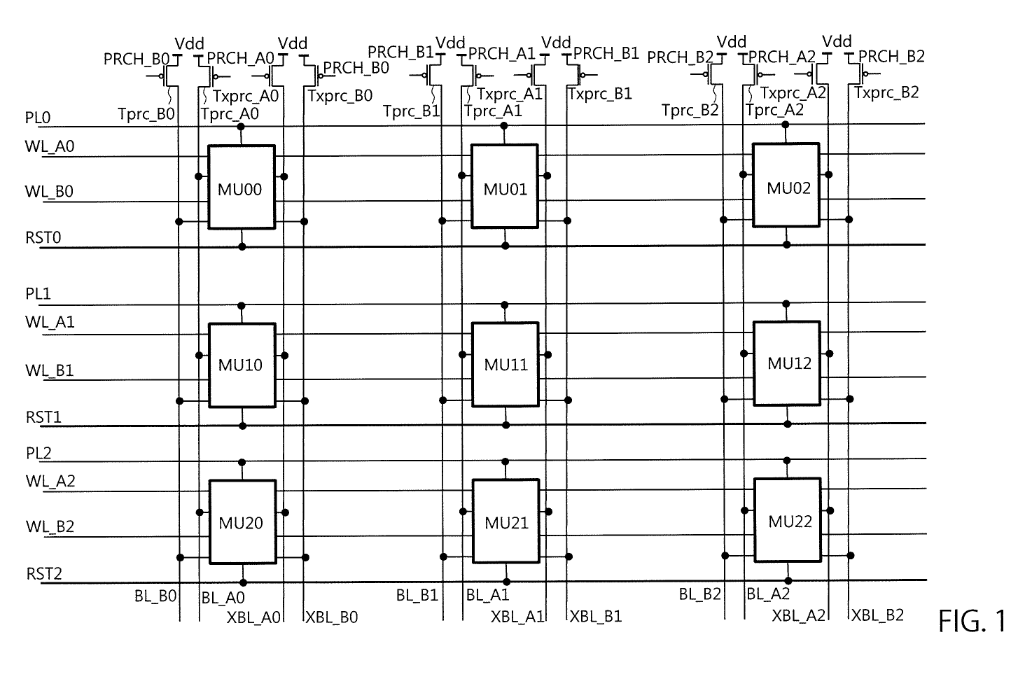

FIG. 1 is a circuit diagram illustrating a configuration example of a semiconductor memory device 1 according to the present embodiment. For example, the semiconductor memory device 1 is a semiconductor memory device in which functions of a ROM (Read-Only Memory) are added to an SRAM (Static Random Access Memory). The semiconductor memory device 1 can be constituted of one semiconductor chip or can be combined with another semiconductor device such as a NAND flash memory to constitute one semiconductor chip.

The semiconductor memory device 1 includes a plurality of memory units MU00 to MU22, a plurality of bit lines BL_A0 to BL_A2, BL_B0 to BL_B2, XBL_A0 to XBL_A2, and XBL_B0 to XBL_B2, a plurality of word lines WL_A0 to WL_A2 and WL_B0 to WL_B2, power-supply lines PL0 to PL2, reset lines RST0 to RST2, precharge transistors Tprc_A0 to Tprc_A2, Tprc_B0 to Tprc_B2, Txprc_A0 to Txprc_A2, and Txprc_B0 to Txprc_B2.

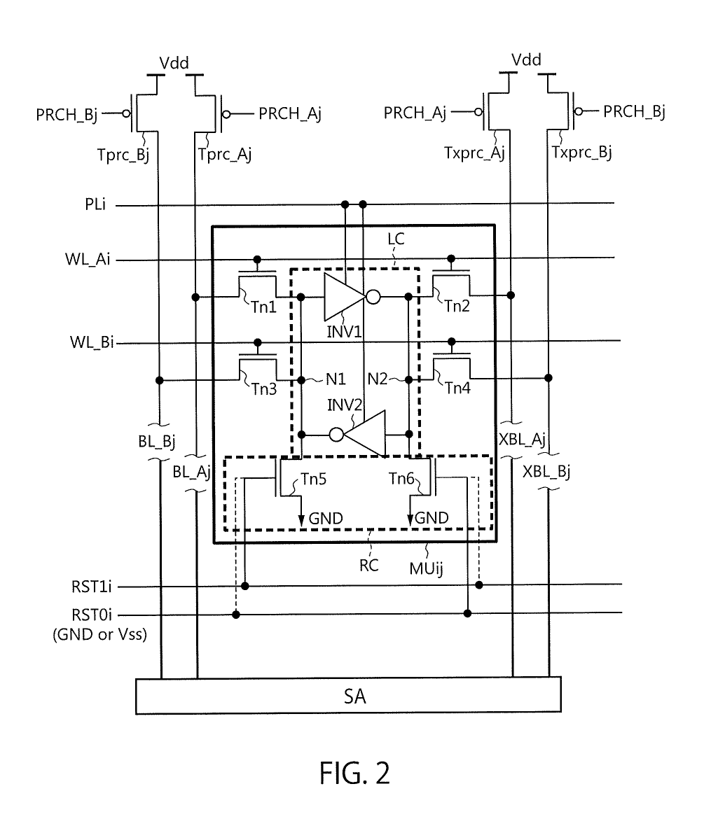

One memory unit MUij (i and j are integers equal to or larger than 0) is provided to correspond to word lines WL_Ai and WL_Bi, a power-supply line PLi, reset lines RST1i and RST0i (illustrated in FIG. 2), bit lines BL_Aj, BL_Bj, XBL_Aj, and XBL_Bj, and precharge transistors Tprc_Aj, Tprc_Bj, Txprc_Aj, and Txprc_Bj. The memory units MUij are provided to correspond to the word lines WL_Ai and WL_Bi and the bit lines BL_Aj, BL_Bj, XBL_Aj and XBL_Bj and are provided at intersections thereof, respectively. The memory units MUij are SRAMs having a ROM function as will be described below and are configured to be capable of storing therein one-bit data, respectively.

In FIG. 1, i and j are 0 to 2. However, i and j can be values equal to or larger than 3. When i and j are 0 to 2, the number of memory units MU is 9. However, the number of memory units MU can be equal to or smaller than 8, or can be equal to or larger than 10.

In the present embodiment, the number of word lines connected to one memory unit MUij is two. However, the number of word lines connected to one memory unit MUij can be one, or can be three or more.

The bit lines connected to one memory unit MUij are two pairs of (BL_Aj and XBL_Aj) and (BL_Bj and XBL_Bj). The bit lines BL_Aj and XBL_Aj transmit signals of logics opposite to each other and the bit lines BL_Bj and XBL_Bj transmit signals of logics opposite to each other, respectively. The bit line pair (BL_Aj and XBL_Aj) corresponds to the word line WL_Ai. Therefore, when the word line WL_Ai is selected, data is transmitted to the bit line pair (BL_Aj and XBL_Aj) to perform read or write of data with respect to the corresponding memory unit MUij. Meanwhile, the bit line pair (BL_Bj and XBL_Bj) corresponds to the word line WL_Bi. Therefore, when the word line WL_Bi is selected, data is transmitted to the bit line pair (BL_Bj and XBL_Bj) to perform read or write of data with respect to the corresponding memory unit MUij.

The precharge transistors Tprc_Aj, Tprc_Bj, Txprc_Aj, and Txprc_Bj are connected between the bit lines BL_Aj, BL_Bj, XBL_Aj, and XBL_Bj and a power source Vdd and are brought into a conduction state to precharge the corresponding bit lines, respectively. For example, when data is to be read via the bit line pair (BL_Aj and XBL_Aj), the precharge transistors Tprc_Aj and Txprc_Aj are brought into a conduction state to precharge the bit line pair (BL_Aj and XBL_Aj) with the power source Vdd in advance. When the word line WL_Ai is selectively raised after the precharge transistors Tprc_Aj and Txprc_Aj are brought into a non-conduction state, a voltage difference occurs in the bit line pair (BL_Aj and XBL_Aj). A sense amplifier (not illustrated) detects the voltage difference in the bit line pair (BL_Aj and XBL_Aj), whereby the logic of data retained in the memory unit MUij can be detected. When data is to be read via the bit line pair (BL_Bj and XBL_Bj), the precharge transistors Tprc_Bj and Txprc_Bj are brought into a conduction state to precharge the bit line pair (BL_Bj and XBL_Bj) with the power source Vdd in advance. When the word line WL_Bi is selectively raised after the precharge transistors Tprc_Bj and Txprc_Bj are brought into a non-conduction state, a voltage difference occurs in the bit line pair (BL_Bj and XBL_Bj). The sense amplifier detects the voltage difference in the bit line pair (BL_Bj and XBL_Bj), whereby the logic of data retained in the memory unit MUij can be detected.

The precharge transistors Tprc_Aj, Tprc_Bj, Txprc_Aj, and Txprc_Bj are each constituted of, for example, a P-type MOSFET (Metal Oxide Semiconductor Field-Effect Transistor). Therefore, when precharge signals PRCH_Aj and PRCH_Bj fall to a low-level voltage, the precharge transistors Tprc_Aj, Tprc_Bj, Txprc_Aj, and Txprc_Aj are brought into a conduction state.

In this way, data retained in the memory unit MUij is read by detecting a voltage difference in the bit line pair (BL_Aj and XBL_Aj) or (BL_Bj and XBL_Bj) precharged in advance, where the voltage difference is generated by selectively raising either the word line WL_Ai or WL_Bi.

An internal configuration of the memory units MUij is explained next.

FIG. 2 is a circuit diagram illustrating an example of the internal configuration of the memory units MUij. Because the memory units MUij respectively have same configurations, one of the configurations is explained.

The memory unit MUij includes a latch circuit LC, a ROM circuit RC, and transistors Tn1 to Tn4. The latch circuit LC includes inverter circuits INV1 and INV2. The inverter circuits INV1 and INV2 are configured in such a manner that the input of one of the circuits is connected to the output of the other circuit and the input of the other circuit is connected to the output of the one circuit. A first node N1 electrically connects the input of the inverter circuit INV1 and the output of the inverter circuit INV2. A second node N2 electrically connects the output of the inverter circuit INV1 and the input of the inverter circuit INV2. The power-supply line PLi is connected to the latch circuit LC to be capable of supplying power to each of the inverter circuits INV1 and INV2. When the power-supply line PLi rises to a high-level voltage (first voltage), the latch circuit LC enables the first and second nodes N1 and N2 to retain data of polarities opposite to each other, respectively. That is, the second node N2 is logically low when the first node N1 is logically high and the second node N2 is logically high when the first node N1 is logically low.

On the other hand, when the power-supply line PLi falls to a low-level voltage (second voltage) lower than the high-level voltage, the potentials of the first and second nodes N1 and N2 become unstable and the latch circuit LC is brought into a state not retaining data. In this way, the latch circuit LC functions as an SRAM and can retain data while being volatile as long as the power-supply line PLi is raised to a high-level voltage.

The transistor Tn1 as a first transistor is connected between the first node N1 and the bit line BL_Aj as a first bit line, and a gate electrode thereof is connected to the word line WL_Ai as a first word line. The transistor Tn2 as a second transistor is connected between the second node N2 and the bit line XBL_Aj as a second bit line, and a gate electrode thereof is connected to the word line WL_Ai similarly to the gate electrode of the transistor Tn1. The transistors Tn1 and Tn2 are each constituted of, for example, an N-type MOSFET. Therefore, when the word line WL_Ai selectively rises, the transistors Tn1 and Tn2 are brought into a conduction state, and the first and second nodes N1 and N2 are connected to the bit lines BL_Aj and XBL_Aj, respectively. Accordingly, data retained in the first and second nodes N1 and N2 or data from the ROM circuit RC is read out to the bit lines BL_Aj and XBL_Aj.

The transistor Tn3 is connected between the first node N1 and the bit line BL_Bj, and a gate electrode thereof is connected to the word line WL_Bi. The transistor Tn4 is connected between the second node N2 and the bit line XBL_Bj, and a gate electrode thereof is connected to the word line WL_Bi similarly to the gate electrode of the transistor Tn3. The transistors Tn3 and Tn4 are each also constituted of, for example, an N-type MOSFET. Therefore, when the word line WL_Bi selectively rises, the transistors Tn3 and Tn4 are brought into a conduction state, and the first and second nodes N1 and N2 are connected to the bit lines BL_Bj and XBL_Bj, respectively. Accordingly, data retained in the first and second nodes N1 and N2 or data from the ROM circuit RC is read out to the bit lines BL_Bj and XBL_Bj. The memory unit MUij according to the present embodiment is a 2-port SRAM or ROM that outputs data of logics opposite to each other from the nodes N1 and N2, respectively.

The ROM circuit RC includes transistors Tn5 and Tn6. The transistor Tn5 as a third transistor is connected between the first node N1 and a ground (a reference voltage source) GND, and a gate electrode thereof is connected to the reset line RST1i as a signal line. The reference voltage source can be either the ground GND or a low-level voltage source Vss and supplies a ground voltage or a low-level voltage. In the following descriptions, the ground GND or the reference voltage source Vss is used as the reference voltage source. The transistor Tn6 as a fourth transistor is connected between the second node N2 and the ground GND, and a gate electrode thereof is connected to the reset line RST0i. The reset line RST0i is a signal line maintained at the ground GND or the reference voltage source Vss. The transistors Tn5 and Tn6 are each constituted of, for example, an N-type MOSFET. Therefore, the ROM circuit RC functions when the reset line RST1i rises to a high-level voltage (fourth voltage) while the power-supply line PLi is caused to fall and the latch circuit LC is not functioning as an SRAM. That is, in response to rising of the reset line RST1i, the transistor Tn5 is brought into a conduction state and the transistor Tn5 electrically connects the first node N1 to the ground GND. The first node N1 is grounded, and charges precharged in the first node N1 are released to the ground GND. Meanwhile, the gate electrode of the transistor Tn6 is grounded via the reset line RST0i and thus the transistor Tn6 is in a non-conduction state regardless of the voltage of the reset line RST1i. Therefore, the second node N2 is in a floating state and not so many charges precharged in the second node N2 are released therefrom. In this case, the potential of the first node N1 lowers faster than the potential of the second node N2, and a potential difference occurs between the first node N1 and the second node N2. A sense amplifier SA amplifies the potential difference between the first node N1 and the second node N2 and detects the amplified potential difference via the bit line pair (BL_Aj and XBL_Aj) or (BL_Bj and XBL_Bj). Accordingly, data in the ROM circuit RC is detected via the first and second nodes N1 and N2.

While the power-supply line PLi has risen and the latch circuit LC is functioning as an SRAM, the reset line RST1i has fallen to a low-level voltage (third voltage). Therefore, the ROM circuit RC electrically disconnects the first and second nodes N1 and N2 from the ground GND. That is, when the reset line RST1i has fallen to a low-level voltage, the ROM circuit RC does not function.

The ROM circuit RC can change the logic of data to be stored in the ROM by selectively changing the connection state of the gate electrodes of the transistors Tn5 and Tn6. For example, in the ROM circuit RC in FIG. 2, the gate electrode of the transistor Tn5 is connected to the reset line RST1i and the gate electrode of the transistor Tn6 is connected to the reset line RST0i. In this case, when the word line WL_Ai or WL_Bi is selectively raised at a time of data read, the potential of the first node N1 becomes lower than the potential of the second node N2. This enables data of a first logic to be detected.

On the other hand, when the gate electrode of the transistor Tn6 is connected to the reset line RST1i and the gate electrode of the transistor Tn5 is connected to the reset line RST0i, the transistor Tn6 is brought into the conduction state and the charges precharged in the second node N2 are released to the ground GND when the reset line RST1i rises. Meanwhile, the transistor Tn5 is in a non-conduction state regardless of the voltage of the reset line RST1i and not so many charges precharged in the first node N1 are released therefrom. In this case, the potential of the second node N2 lowers faster than the potential of the first node N1. In this manner, data of a second logic opposite to the first logic is detected.

The logic of data stored in the ROM circuit RC is set at the time of manufacturing the semiconductor memory device 1 and is determined by a physical structure. Therefore, the data in the ROM circuit RC cannot be changed after manufacturing the semiconductor memory device 1. Accordingly, when the memory unit MUij is operated in a ROM mode, the memory unit MUij outputs data of a predetermined logic, which is set in advance and is non-rewritable, from the ROM circuit RC. When the memory unit MUij is operated in an SRAM mode, the memory unit MUij outputs volatile data that has been written to the latch circuit LC and is rewritable regardless of the data in the ROM circuit RC.

In this way, the memory unit MUij according to the present embodiment can function as an SRAM when the power-supply line PLi has risen, and can function as a ROM by activating the ROM circuit RC due to rising of the reset line RST1i when the power-supply PLi has fallen. The gate electrode of the transistor Tn5 or Tn6 connected to the reset line RST0i can be connected directly to the ground GND or the reference voltage source Vss.

The memory unit MUij according to the present embodiment is not a simple combination of an SRAM circuit and a ROM circuit but is configured in a size as small as possible in which the bit lines BL_Aj, XBL_Aj, BL_Bj, and XBL_Bj, the word lines WL_Ai and WL_Bi, the transistors Tn1 to Tn4, and the nodes N1 and N2 are shared by the latch circuit LC and the ROM circuit RC. That is, the memory unit MUij according to the present embodiment has a quite small layout area while having the functions of both an SRAM and a ROM. The memory units MUij are provided as many as i and j. Therefore, the entire area of the semiconductor memory device 1 can be reduced by reduction of the layout area of each of the memory units MUij.

An operation of the semiconductor memory device 1 according to the present embodiment is explained next.

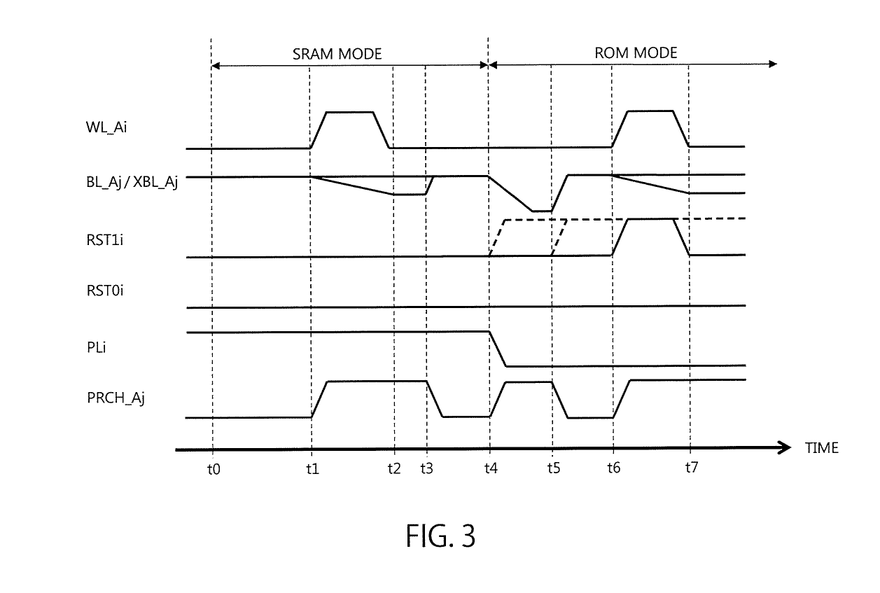

FIG. 3 is a flowchart illustrating an example of a data read operation of the memory unit MUij according to the present embodiment. In FIG. 3, voltages of respective lines in the SRAM mode are illustrated first and voltages of the respective lines in the ROM mode are illustrated next. The memory units MUij can operate in a same manner and thus an operation of one of the memory units MUij is explained. Because FIG. 3 illustrates a case where the word line WL_Ai is selected, voltages of the precharge signals PRCH_Aj and the bit line pair BL_Aj and XBL_Aj corresponding to the word line WL_Ai are illustrated. However, the word line WL_Bi can be selected, of course. In the case of selecting the word line WL_Bi, the memory units MUij operate in such a manner that the voltages of the precharge signal PRCH_Bj and the bit line pair BL_Bj and XBL_Bj corresponding to the word line WL_Bi are as illustrated in FIG. 3.

### SRAM Mode

First, from t0 to t1, the memory unit MUij is in a standby state of the SRAM mode as a first mode. In the standby state of the SRAM mode, the power-supply line PLi is raised and the latch circuit LC has signals (1-bit data) of logics opposite to each other stored in the nodes N1 and N2, respectively. Accordingly, the memory unit MUij is in a state of being operable as an SRAM.

In the SRAM mode, the reset line RST1i has fallen to a low-level voltage and the reset line RST1i has brought the transistor Tn5 (or Tn6) into a non-conduction state. Therefore, the ROM circuit RC is not functioning in the SRAM mode.

In the standby state, the word lines WL_Ai and WL_Bi are caused to fall to a low-level voltage and both are in a non-selected state. In the standby state, the precharge signal PRCH_Aj is caused to fall to a low-level voltage and the precharge transistors Tprc_Aj and Txprc_Aj are in a conduction state. Therefore, the bit line pair BL_Aj and XBL_Aj is precharged with a voltage of the power source Vdd in the standby state.

In the standby state, the precharge signal PRCH_Bj can be maintained at a high-level voltage to bring the bit line pair BL_Bj and XBL_Bj to a floating state without being precharged. This can reduce power consumption in the standby state. In this case, before raising the word line WL_Ai at t1, it is necessary to cause the precharge signal PRCH_Bj to fall to a low-level voltage once to precharge the bit line pair BL_Bj and XBL_Bj.

In a period from t1 to t3, at the same time as the precharge signal PRCH_Aj is raised to a high-level voltage to end precharging of the bit line pair BL_Aj and XBL_Aj or immediately thereafter, the word line WL_Ai is raised to a high-level voltage. Accordingly, the transistors Tn1 and Tn2 transmit the voltages of the corresponding nodes N1 and N2 to the bit lines BL_Aj and XBL_Aj, respectively. At this time, a voltage difference occurs between the bit line pair BL_Aj and XBL_Aj according to signals of opposite logics retained in the node N1 and N2.

For example, when a high-level voltage is held in the second node N2 and a low-level voltage is held in the first node N1, the voltage of the bit line BL_Aj gradually lowers while the bit line XBL_Aj is maintained at the high-level voltage. The sense amplifier SA detects the voltage difference between the bit line pair BL_Aj and XBL_Aj at the same time as the word line WL_Ai is caused to fall at t2 or immediately thereafter. Accordingly, the logic (the first logic, for example) of data retained in the latch circuit LC is detected.

Conversely, when a high-level voltage is held in the first node N1 and a low-level voltage is held in the second node N2, the voltage of the bit line XBL_Aj gradually lowers while the bit line BL_Aj is maintained at the high-level voltage. The sense amplifier SA detects the voltage difference between the bit line pair BL_Aj and XBL_Aj at the same time as the word line WL_Ai is raised at t2 or immediately thereafter. Accordingly, the logic (the second logic, for example) of data retained in the latch circuit LC is detected.

By causing the precharge signal PRCH_Aj to fall to a low-level voltage between t3 and t4, the memory unit MUij enters the standby state of the SRAM mode. Thereafter, the SRAM mode can be repeated or the memory unit MUij can shift to the ROM mode.

### ROM Mode

From t4 to t5, the memory unit MUij is in a standby state of the ROM mode. In the ROM mode, the power-supply line PLi falls and the power-supply line PLi stops supplying power to the latch circuit LC. Therefore, the latch circuit LC does not function as an SRAM. Because the power-supply line PLi and the reset line RST1i have fallen in the ROM mode, the power consumption is small while the signal state of the nodes N1 and N2 are unstable.

In the standby state, the word lines WL_Ai and WL_Bi have fallen to a low-level voltage and both are in a non-selected state. Further, in the standby state, the precharge signal PRCH_Aj rises to a high-level voltage and the precharge transistors Tprc_Aj and Txprc_Aj are in a non-conduction state. Accordingly, in the standby state, the bit line pair BL_Aj and XBL_Aj are in a floating state. This can further reduce the power consumption in the standby state.

In a period from t5 to t6, the precharge signal PRCH_Aj is caused to fall to a low-level voltage to precharge the bit line pair BL_Aj and XBL_Aj with the voltage of the power source Vdd.

In a period from t6 to t7, at the same time as the precharge signal PRCH_Aj is raised to a high-level voltage to end precharging of the bit line pair BL_Aj and XBL_Aj or immediately thereafter, the word line WL_Ai and the reset line RST1i are raised to a high-level voltage. By raising the reset line RST1i, the transistor Tn5 (or Tn6) connected to the reset line RST1i is brought into a conduction state to connect the node N1 (or N2) to the ground GND. The transistor Tn6 (or Tn5) is kept in a non-conduction state to electrically disconnect the node N2 (or N1) from the ground GND. Furthermore, in response to raising of the word line WL_Ai, a voltage difference occurs between the bit line pair BL_Aj and XBL_Aj according to a voltage difference between the nodes N1 and N2.

For example, when the gate electrode of the transistor Tn5 is connected to the reset line RST1i and the gate electrode of the transistor Tn6 is connected to the reset line RST0i (see solid lines in FIG. 2), the transistor Tn5 grounds the first node N1. The transistor Tn6 is kept in a non-conduction state to electrically disconnect the second node N2 from the ground GND and keep the second node N2 in the floating state. In this case, the voltage of the bit line BL_Aj gradually lowers while the bit line XBL_Aj is maintained at the high-level voltage. Therefore, at the same time as the word line WL_Ai is caused to fall at t7 or immediately thereafter, the sense amplifier SA detects the voltage difference between the bit line pair BL_Aj and XBL_Aj. Accordingly, the logic (the first logic, for example) of data retained in the ROM circuit RC is detected.

Conversely, when the gate electrode of the transistor Tn5 is connected to the reset line RST0i and the gate electrode of the transistor Tn6 is connected to the reset line RST1i (see dashed lines in FIG. 2), the transistor Tn6 is brought into a conduction state and grounds the second node N2. The transistor Tn5 is kept in a non-conduction state to electrically disconnect the first node N1 from the ground GND and keep the first node N1 in the floating state. In this case, the voltage of the bit line XBL_Aj gradually lowers while the bit line BL_Aj is kept at the high-level voltage. Therefore, at the same time as the word line WL_Ai is caused to fall at t7 or immediately thereafter, the sense amplifier SA detects the voltage difference between the bit line pair BL_Aj and XBL_Aj. Accordingly, the logic (the second logic, for example) of data retained in the ROM circuit RC is detected.

By causing the word line WL_Ai and the reset line RST1i to fall after t7, the memory unit MUij enters the standby state of the ROM mode. Thereafter, the ROM mode can be repeated or the memory unit MUij can shift to the SRAM mode. As described above, the semiconductor memory device 1 according to the present embodiment has the SRAM mode in which the power-supply line PLi is raised to store data in the latch circuit LC, and the ROM mode in which the power-supply line PLi is caused to fall and the reset line RST1i is raised to cause the ROM circuit RC to function.

Although a data write operation is not illustrated, it suffices to selectively drive the word line WL_Ai to bring the transistors Tn1 and Tn2 to a conduction state and transmit voltages from the bit lines BL_Aj and XBL_Aj to the first and second nodes N1 and N2, respectively, in the SRAM mode. In the ROM mode, data write cannot be performed.

In this way, in the SRAM mode, the power-supply line PLi supplies power to the latch circuit CL, whereby the latch circuit LC retains data therein. Meanwhile, the reset line RST1i does not supply power to the ROM circuit RC and the ROM circuit RC electrically disconnects the both nodes N1 and N2 from the ground GND

In the ROM mode, the power-supply line PLi stops power supply to the latch circuit LC, which prevents the latch circuit LC from retaining data therein. Meanwhile, the reset line RST1i supplies power to the ROM circuit RC, whereby the ROM circuit RC electrically connects either the node N1 or N2 to the ground GND.

As described above, the memory unit MUij according to the present embodiment can function as an SRAM when the power-supply line PLi rises and can function as a ROM circuit RC in response to rising of the reset line RST1i when the power-supply line PLi falls.

### Modification

In the embodiment described above, the reset line RST1i is raised or caused to fall in the same timing as the word line WL_Ai as indicated from t6 to t7 in FIG. 3. However, the reset line RST1i can be raised before the raising timing of the word line WL_Ai (at t4 or t5, for example) as indicated by dashed lines.

The reset line RST1i can maintain the high-level voltage after the falling timing of the word line WL_Ai. That is, the reset line RST1i can continue the high-level voltage state in the ROM mode. While power consumption of the reset line RST1i may be increased in this case, no problem occurs in the operation or function of the ROM circuit RC.

On the other hand, when the memory unit MUij is accessed frequently in the ROM mode, that is, the operation from t5 to t7 is performed frequently for a short time, the raising operation and the falling operation of the reset line RST1i are performed frequently. In this case, charging and discharging of the reset line RST1i are repeated frequently for a short time and thus there is a risk that the power consumption is increased. Therefore, when the memory unit MUij is to be accessed frequently in the ROM mode, it may be preferable that the reset line RST1i continues the high-level voltage state as in the present modification to reduce the power consumption.

### Layout

A layout of the semiconductor memory device 1 according to the present embodiment is explained next.

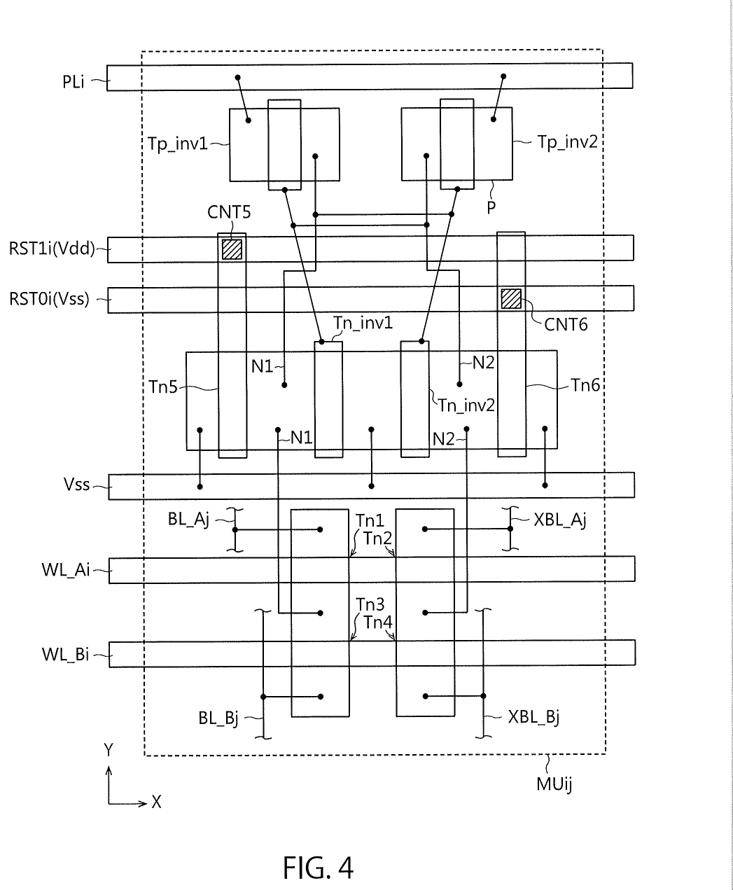

FIG. 4 is a plan view illustrating an example of a schematic layout of the memory unit MUij. In FIG. 4, lines other than the power-supply line PLi, the reset lines RST1i and RST0i, a line for the reference voltage source Vss, and the word lines WL_Ai and WL_Bi extending in an X direction are simplified and connection relations thereof are illustrated. An equivalent circuit of the memory unit MUij illustrated in FIG. 4 is indicated by the memory unit MUij in FIG. 2.

In the layout of the memory unit MUij according to the present embodiment, respective N-type transistors Tn_inv1 and Tn_inv2 of the inverter circuits INV1 and INV2 are placed side by side in the extending direction (the X direction) of the word lines WL_Ai and WL_Bi. The N-type transistors Tn5 and Tn6 of the ROM circuit RC are placed side by side next (in the X direction) to the N-type transistors Tn_inv1 and Tn_inv2. That is, the N-type transistors Tn_Inv1 and Tn_inv2 of the latch circuit LC and the N-type transistors Tn5 and Tn6 of the ROM circuit RC are placed in parallel in the X direction.

Sources of the transistors Tn5 and Tn6 are connected to the reference voltage source Vss. Drains of the transistors Tn5 and Tn6 are connected to the nodes N1 and N2, respectively. The gate electrodes of the transistors Tn5 and Tn6 are connected to either the reset line RST1i or RST0i via contacts CNT5 and CNT6, respectively. The reset line RST1i is a signal line that maintains a low-level voltage (Vss or GND) in the SRAM mode and rises to a high-level voltage (Vdd) in the ROM mode. That is, the voltage of the reset line RST1i is variable between a low-level voltage as the third voltage and a high-level voltage as the fourth voltage. Meanwhile, the reset line RST0i is a signal line maintained at a low-level voltage (Vss or GND).

For example, when the gate electrode of the transistor Tn5 is connected to the reset line RST1i and the gate electrode of the transistor Tn6 is connected to the reset line RST0i, the ROM circuit RC stores therein the first logic (data “1”, for example). When the gate electrode of the transistor Tn5 is connected to the reset line RST0i and the gate electrode of the transistor Tn6 is connected to the reset line RST1i, the ROM circuit RC stores therein the second logic (data “0”, for example). The gate electrode of the transistor Tn5 or Tn6 can be connected to a low-level voltage (Vss or GND) not via the reset line RST0i.

In this way, the logic of data written to the ROM circuit RC depends on formation positions of the contacts CNT5 and CNT6 in a manufacturing process of the ROM circuit RC and is determined by a physical structure. The transistor Tn5 (or Tn6) connected to the reset line RST1i connects the node N1 (or N2) to the reference voltage source Vss in response to rising of the reset line RST1i and causes charges accumulated in the node N1 (or N2) to flow to the reference voltage source Vss. This determines the logic of the data stored in the ROM circuit RC.

Sources of the transistors Tn_inv1 and Tn_inv2 are connected to the reference voltage source Vss. Drains of the transistors Tn_inv1 and Tn_inv2 are connected to the nodes N1 and N2, respectively. A gate electrode of the transistor Tn_inv1 is connected to the node N2 and a gate electrode of the transistor Tn_inv2 is connected to the node N1.

Respective P-type transistors Tp_inv1 and Tp_inv2 of the inverter circuits INV1 and INV2 are located at positions displaced from the N-type transistors Tn_inv1 and Tn_inv2 in the extending direction (a Y direction) of the bit lines BL_Aj and XBL_Aj. Sources of the transistors Tp_inv1 and Tp_inv2 are connected to the power-supply line PLi and maintain a high-level voltage in the SRAM mode while maintaining a low-level voltage in the ROM mode. A drain of the transistor Tp_inv1 is connected to the node N1. A drain of the transistor Tp_inv2 is connected to the node N2. That is, the gate electrode of the transistor Tn_inv1, a gate electrode of the transistor Tp_inv1 and the drains of the transistors Tn_inv2, Tp_inv2, and Tn6 are all electrically connected to the second node N2. The gate electrode of the transistor Tn_inv2, a gate electrode of the transistor Tp_inv2, and the drains of the transistors Tn_inv1, Tp_inv1, and Tn5 are all electrically connected to the first node N1.

Accordingly, the transistors Tn_inv1 and Tp_inv1 constitute the inverter circuit INV1, and the transistors Tn_inv2 and Tp_inv2 constitute the inverter circuit INV2. The transistors Tn5 and Tn6 constitute the ROM circuit RC.

The first node N1 is electrically connected further to the drains of the transistors Tn1 and Tn3. The second node N2 is electrically connected further to the drains of the transistors Tn2 and Tn4. The transistors Tn1 to Tn4 are also located at positions displaced from the N-type transistors Tn_inv1 and Tn_inv2 in the Y direction while located on the opposite side to the P-type transistors Tp_inv1 and Tp_inv2.

The word line WL_Ai functions as the gates of the transistors Tn1 and Tn2, and the word line WL_Bi functions as the gates of the transistors Tn3 and Tn4. One of the source and the drain of the transistor Tn1 is connected to the node N1 and the other thereof is connected to the bit line BL_Aj. One of the source and the drain of the transistor Tn2 is connected to the node N2 and the other thereof is connected to the bit line XBL_Aj. One of the source and the drain of the transistor Tn3 is connected to the node N1 along with the transistor Tn1 and the other thereof is connected to the bit line BL_Bj. One of the source and the drain of the transistor Tn4 is connected to the node N2 along with the transistor Tn2 and the other thereof is connected to the bit line XBL_Bj. Accordingly, the transistors Tn1 to Tn4 function as data transfer transistors.

The power-supply line PLi and the reset lines RST1i and RST0i extend in the X direction substantially in parallel to the word lines WL_Ai and WL_Bi. Therefore, as can be understood from FIG. 1, the power-supply line PLi and the reset lines RST1i and RST0i are connected in common to plural memory units MUij connected in common to the word lines WL_Ai and WL_Bi. The power-supply line PLi is connected in common to the latch circuits LC of the plural memory units MUij. The reset line RST1i is selectively connected to the gate electrodes of either the transistors Tn5 or Tn6 (ones of the transistors Tn5 and Tn6) in the memory units MUij and the reset line RST0i is connected to the gate electrodes of the other ones. The power-supply lines PLi can execute voltage control independently. The reset lines RST1i also can execute voltage control independently. Therefore, the semiconductor memory device 1 according to the present embodiment can selectively set a mode to either the SRAM mode or the ROM mode with respect to plural memory units MUij that share the word lines WL_Ai and WL_Bi.

For example, plural memory units MUij connected in common to certain word lines WL_Ai and WL_Bi are operated in the SRAM mode by raising the power-supply line PLi corresponding thereto. At this time, the reset line RST1i is caused to fall. On the other hand, plural memory units MUkj connected in common to other word lines WL_Ak and BL_Bk (k is a natural number where k≠i) are operated in the ROM mode by causing a power-supply line PLk corresponding thereto to fall and raising the reset line RST1k.

Accordingly, when the entire semiconductor memory device 1 is used first as a ROM and then data in the ROM is to be rewritten, only memory units MUij in a row connected to corresponding word lines WL_Ai and WL_Bi can be selectively changed to the SRAM mode. Information of word lines to be used in the ROM mode and information of word lines to be used in the SRAM mode can be stored in other memories (such as a register, a fuse, or a NAND flash memory, not illustrated) provided to correspond to the respective word lines. Alternatively, word lines to be used in the ROM mode and word lines to be used in the SRAM mode can be determined by referring to the value of a redundant cell in the semiconductor memory device 1.

As described above, the transistors Tn5 and Tn6 constituting the ROM circuit RC are placed in parallel next (in the X direction) to the transistors Tn_inv1 and Tn_inv2 constituting the inverter circuit. Accordingly, addition of the transistors Tn5 and Tn6 hardly increases the layout area, or causes only a very slight increase. Therefore, the semiconductor memory device 1 according to the present embodiment can reduce the layout area while having the functions of both an SRAM and a ROM.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a latch circuit including a first node and a second node being capable of retaining data of polarities opposite to each other, respectively;
a first transistor electrically connected between the first node and a first bit line and having a gate electrode electrically connected to a word line;
a second transistor electrically connected between the second node and a second bit line and having a gate electrode electrically connected to the word line;
a power-supply line electrically connected to the latch circuit;
a third transistor electrically connected between the first node and a reference voltage source;
a fourth transistor electrically connected between the second node and the reference voltage source and having a gate electrode electrically connected to the reference voltage source; and
a signal line electrically connected to a gate electrode of the third transistor, wherein
the power-supply line supplies a first voltage to the latch circuit and the signal line brings the third transistor to a non-conduction state in a first mode, and
the power-supply line supplies a second voltage to the latch circuit and the signal line brings the third transistor to a conduction state and electrically connects the first node to the reference voltage source in a second mode.

2. The device of claim 1, wherein
the latch circuit stores data in the first and second nodes in the first mode, and
the third transistor electrically connects the first node to the reference voltage source and the fourth transistor electrically disconnects the second node from the reference voltage source in the second mode.

3. The device of claim 1, wherein the first and second transistors transmit voltages of the first and second nodes to the first and second bit lines, respectively, in response to selection of the word line at a time of data read in the first and second modes.

4. The device of claim 1, wherein
the first and second transistors transmit voltages from the first and second bit lines to the first and second nodes, respectively, in response to selection of the word line at a time of data write in the first mode, and
data write is not performed in the second mode.

5. The device of claim 1, wherein
in the first mode, the latch circuit functions as an SRAM (Static Random Access Memory), and
in the second mode, the latch circuit and the third and fourth transistors function as a ROM (Read-Only Memory).

6. The device of claim 2, wherein
in the first mode, the latch circuit functions as an SRAM, and
in the second mode, the latch circuit and the third and fourth transistors function as a ROM.

7. The device of claim 3, wherein
in the first mode, the latch circuit functions as an SRAM, and
in the second mode, the latch circuit and the third and fourth transistors function as a ROM.

8. The device of claim 4, wherein
in the first mode, the latch circuit functions as an SRAM, and
in the second mode, the latch circuit and the third and fourth transistors function as a ROM.

9. The device of claim 1, wherein the power-supply line extends substantially in parallel to the word line.

10. The device of claim 2, wherein the power-supply line extends substantially in parallel to the word line.

11. The device of claim 1, wherein the signal line extends substantially in parallel to the word line.

12. The device of claim 2, wherein the signal line extends substantially in parallel to the word line.

13. The device of claim 1, wherein
assuming the latch circuit and the first to fourth transistors as one unit,
a plurality of the units are provided to correspond to the word line and the first and second bit lines,
the units are connected in common to the word line,
the power-supply line is connected in common to the latch circuits of the units, and
the signal line is selectively connected to gate electrodes of either the third transistors or the fourth transistors in the units.

14. The device of claim 2, wherein
assuming the latch circuit and the first to fourth transistors as one unit,
a plurality of the units are provided to correspond to the word line and the first and second bit lines,
the units are connected in common to the word line,
the power-supply line is connected in common to the latch circuits of the units, and
the signal line is selectively connected to gate electrodes of either the third transistors or the fourth transistors in the units.

15. The device of claim 13, wherein
ones of the units having the third transistors connected to the signal line output data of a first logic in the second mode, and
ones of the units having the fourth transistors connected to the signal line output data of a second logic opposite to the first logic in the second mode.

16. The device of claim 14, wherein
ones of the units having the third transistors connected to the signal line output data of a first logic in the second mode, and
ones of the units having the fourth transistors connected to the signal line output data of a second logic opposite to the first logic in the second mode.

17. A semiconductor device comprising:
a latch circuit including a first node and a second node being capable of retaining data of polarities opposite to each other, respectively;
a power-supply line electrically connected to the latch circuit;
a ROM circuit electrically connected between the first node and a reference voltage source and between the second node and the reference voltage source; and
a signal line electrically connected to the ROM circuit, wherein
the power-supply line supplies a first voltage to the latch circuit to enable the latch circuit to retain data, and the signal line supplies a third voltage to the ROM circuit to enable the ROM circuit to electrically disconnect the first and second nodes from the reference voltage source in a first mode, and
the power-supply line supplies a second voltage to the latch circuit to cause the latch circuit not to retain data, and the signal line supplies a fourth voltage to the ROM circuit to enable the ROM circuit to electrically connect either the first node or the second node to the reference voltage source in a second mode.
